(19) United States
(12) Patent Application Publication
(10) Pub. No.: US 2020/0153926 A1
(43) Pub. Date: May 14, 2020

(54) SCALABLE VEHICLE DATA COMPRESSION SYSTEMS AND METHODS

(71) Applicant: Toyota Motor North America, Inc., Plano, TX (US)

(72) Inventor: Robert D. SLATER, Murphy, TX (US)

(73) Assignee: Toyota Motor North America, Inc., Plano, TX (US)

(21) Appl. No.: 16/185,547

(22) Filed: Nov. 9, 2018

(51) Int. Cl. H04L 29/08; H04W 4/38; H04W 4/44; H04W 4/46; H03M 7/30; G06F 9/50; H04W 28/06

(52) U.S. Cl. CPC H04L 67/2828; H04W 4/38; H04W 4/44; H04W 28/06; H03M 7/30; G06F 9/505; H04W 4/46

(57) ABSTRACT

A scalable vehicle data compression system includes one or more processors, one or more memory modules communicatively coupled to the one or more processors and machine readable instructions stored in the one or more memory modules and upon execution by the one or more processors, performing at least (i) analyzing a data stream, (ii) determining a type of the data stream, an estimated usage of a network bandwidth, a current processing load of the processor, or a combination thereof, (iii) determining a level of compression based on the data type, the estimated usage of the network bandwidth, the current processing load of the processor, or a combination thereof, and (iv) compressing the data stream with the processor based on the determined level of compression.

### TECHNICAL FIELD

Embodiments described herein generally relate to systems and methods for compressing vehicle data with scalability and, more specifically, to systems and methods for compressing vehicle data with scalability at a vehicle, or a computing device remote from a vehicle in order to adjust the level of compression based on various factors.

### BACKGROUND

Compressing data for efficient transfer and storage is desirable in the data processing field. Various data processing devices may compress data prior to transmission of the data over a network. Compression of data is performed to reduce the size or volume of data for transmission or storage. In particular, with respect to transmission of data, available network bandwidth capacity may be a limited resource. The cost required to transmit data has significantly increased as the size or volume of data involved with transmission dramatically increases. Reducing the size or volume of data for transmission through compression may potentially result in significant cost savings. Moreover, compression of data consumes a relatively low level of computing power and various compression algorithms are available for implementation.

A large number of vehicles are equipped to transmit and receive data via cellular and/or Wi-Fi networks. Data generated by vehicles have significantly increased and are expected to further increase. For instance, autonomous vehicles involve and require a significant amount of data for performing self-driving. Transmission of the data between vehicles, between vehicles and service providers, and/or between vehicles and cloud servers, etc. may require significant consumption of the limited data transmission bandwidth. Numerous factors are relevant to and affect data transmission from vehicles using the bandwidth.

These factors may be based on mobility of vehicles, types of data, data traffic from and to vehicles, system structures of vehicle computing systems, etc. For instance, rush hour traffic may not only congest highways but also potentially congest network traffic. Accordingly, there is a need to provide systems and methods for compressing vehicle data to maximize effective and efficient use of limited network bandwidth. Also, there is a need to provide systems and methods for compressing vehicle data with scalability to address various factors affecting the data transmission from vehicles over a network.

### SUMMARY

In one embodiment, a scalable vehicle data compression method includes detecting and capturing vehicle data with a group of sensors, processing and analyzing one or more data streams including the vehicle data with a processor, and determining (i) a data type of the data stream, (ii) an estimated usage of a network bandwidth, (iii) a current processing load of the processor, or a combination thereof. The scalable vehicle data compression method further includes determining a level of compression based on the data type, the estimated usage of the network bandwidth, the current processing load of the processor, or a combination thereof, compressing the one or more data streams with the processor based on the determined level of compression, and transmitting a compressed data stream over a network.

In another embodiment, a scalable vehicle data compression method, includes receiving, at a receiver comprising a processor and a memory, a plurality of data streams from a group of mobile data sources, storing in the memory estimated usage data of a network data traffic associated with a data transmission time and a data transmission location, determining a data type of the data stream, (ii) an estimated usage of a network bandwidth, (iii) a current processing load of the processor, or a combination thereof, retrieving the estimated usage data, determining a level of compression based on the data type, the estimated usage of the network data traffic, the current processing load of the processor, or a combination thereof, compressing the plurality of data streams with the processor based on the determined level of compression, and transmitting one or more compressed data streams over a network to a cloud server.

In another embodiment, a scalable vehicle data compression system, includes a group of sensors arranged on-board of a vehicle and operable to detect and capture vehicle data, one or more processors coupled to the group of sensors and operable to receive one or more data streams including the vehicle data, one or more memory modules communicatively coupled to the one or more processors; and machine readable instructions stored in the one or more memory modules and upon execution by the one or more processors, performing at least the following: analyzing the one or more data streams including the vehicle data; determining (i) a data type of the data stream, (ii) an estimated usage of a network bandwidth, (iii) a current processing load of the processor, or a combination thereof; determining a level of compression based on the data type, the estimated usage of the network bandwidth, the current processing load of the processor, or a combination thereof; and compressing the one or more data streams with the processor based on the determined level of compression; and a communication unit that transmits a compressed data stream over a network.

In another embodiment, a scalable vehicle data compression system includes a processor, a data communication unit operable to receive a plurality of data streams from a group of mobile data sources, and one or more memory coupled to the processor and configured to store estimated usage data of a network data traffic associated with a data transmission time and a data transmission location. The one or more memory further stores machine readable instructions stored in the one or more memory and upon execution by the one or more processors, performing at least determining (i) a data type of the data stream, (ii) an estimated usage of a network bandwidth, (iii) a current processing load of the processor, or a combination thereof, retrieving the estimated usage data, determining a level of compression based on the one or more data types, the estimated usage of the network data traffic, the current processing load of the processor, or a combination thereof, and compressing the plurality of data streams with the processor based on the determined level of compression. The data communication unit is further operable to transmit one or more compressed data streams over a network to a cloud server.

These and additional features provided by the embodiments of the present disclosure will be more fully understood in view of the following detailed description, in conjunction with the drawings.

### BRIEF DESCRIPTION OF THE DRAWINGS

The embodiments set forth in the drawings are illustrative and exemplary in nature and not intended to limit the disclosure. The following detailed description of the illustrative embodiments can be understood when read in conjunction with the following drawings, where like structure is indicated with like reference numerals and in which:

FIG. 1 schematically depicts a vehicle data compression system according to one or more embodiments shown and described herein;

FIG. 2 schematically depicts a block diagram of a head unit of the vehicle data compression system of FIG. 1;

FIG. 3 depicts a flow chart of a method of compressing vehicle driving data according to one or more embodiments shown and described herein;

FIG. 4 depicts a flow chart of compressing vehicle driving data with scalability according to one or more embodiments shown and described herein;

FIG. 5 depicts a flow chart of a compression scalability program according to one or more embodiments shown and described herein; and

FIG. 6 schematically depicts different compression points of the vehicle data compression system of FIG. 1.

### DETAILED DESCRIPTION

Connected cars are equipped to communicate with other devices, utilizing connectivity available via wireless and/or cellular networks. Connected cars may be connected to and communicate with the surroundings. Connected cars may communicate via a variety of communication models, including Vehicle to Infrastructure (“V2I”), Vehicle to Vehicle (“V2V”), Vehicle to Cloud (“V2C”), and Vehicle to Everything (“V2X”) communication models. A V2I communication model facilitates the communication between a vehicle and one or more infrastructure devices, which may enable the exchange of data generated by a vehicle and information about the infrastructure. A V2V communication model facilitates the communication between vehicles and may allow for the exchange of data generated by surrounding vehicles, including speed and position information of surrounding vehicles. A V2C communication model facilitates the exchange of information between a vehicle and a cloud system. A V2X communication model interconnects all types of vehicles and infrastructure systems with another.

As discussed above, connected cars operate to capture and generate a large amount of data about a vehicle, surrounding vehicles, the environment, etc. Connected cars may seamlessly transmit such data to surrounding vehicles, a cloud server, other infrastructure, etc. and communicate with them via the network. The embodiments disclosed herein include systems and methods for compressing vehicle data prior to transmission of the vehicle data over a network in order to provide fast, efficient and cost effective data transfer to external servers, such as edge servers, a central server, and/or any other remote servers. The embodiments of the systems and methods for compressing vehicle data described here may provide considerable advantages for use with connected cars in reducing the size or volume of data and using the network bandwidth more effectively.

In the embodiments disclosed herein, compression of the vehicle data may reduce the size or volume of vehicle data for transmission, storage, or other uses. Compression of the vehicle data may not require high processing power by a processor residing in a vehicle and may not interfere with performance of the processor. In the embodiments disclosed herein, compression of the vehicle data may be performed with scalability and flexibility rather than performed uniformly. In other words, compression may be performed by adjusting a level of compression, based on multiple factors relevant to the adjustment. Additionally, or alternatively, compression of the vehicle data may involve encryption of vehicle data and improve data security of the vehicle data.

In the embodiments disclosed herein, compression may be performed at different points such as at a vehicle, at a remote server, at a receiver, etc. The level of compression may vary depending on where compression of vehicle data takes place, in light of various relevant factors applicable to the devices and systems that perform compression as well as the status of bandwidth consumption and availability. The various systems and methods for compressing vehicle data with scalability will be described in more detail herein with specific reference to the corresponding drawings.

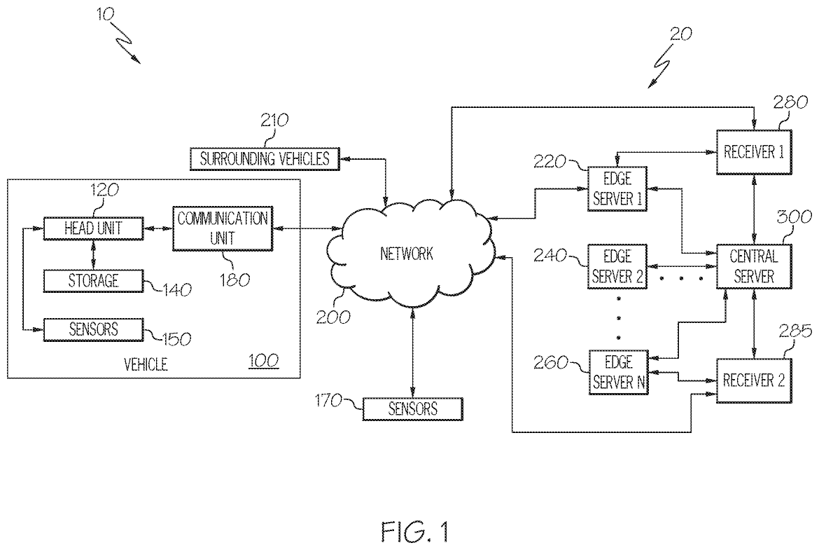

FIG. 1 schematically depicts a connected cars system 10 including a vehicle 100 and a cloud computing system 20. The vehicle 100 includes a head unit 120, storage 140 and a group of sensors including various sensors 150. The head unit 120 controls operation of the vehicle 100 based on data points captured and sent from the sensors 150. The storage 140 is coupled to the head unit 120 and stores a set of data points under the control of the head unit 120. The sensors 150 include various types of sensors used in the vehicle 100. In some embodiments, the sensors 150 include one or more cameras, an accelerometer, a proximity sensor, a braking sensor, a motion sensor, etc. The sensors 150 used in the vehicle 100 may not be limited thereto and other sensors can be implemented.

In some embodiments, the vehicle 100 also receives data points from a group of sensors 170 that may be arranged outside of the vehicle 100. For example, the sensors 170 may be arranged on or near buildings such as a parking structure, municipal infrastructure, the surroundings of the vehicle 100, etc. The vehicle 100 may receive data points from the sensors 170 via the network 200. In other embodiments, the vehicle 100 may receive the data points from surrounding vehicles 210 via a V2V communication channel. Like the sensors 150, various types of sensors such as one or more cameras, an accelerometer, a proximity sensor, a braking sensor, a motion sensor, etc. may be used as the sensors 170.

As shown in FIG. 1, the vehicle 100 includes a communication unit 180 that exchanges data and information between the vehicle 100 and a network 200. As shown in FIG. 1, the vehicle 100 may be connected and communicate with one or more edge servers 220, 240 and 260. The edge servers 220, 240 and 260 may be connected and communicate with a central server 300. The central server 300 may be in communication with receivers 280, 285. The receivers 280, 285 also communicate with the vehicles 100 and 210.

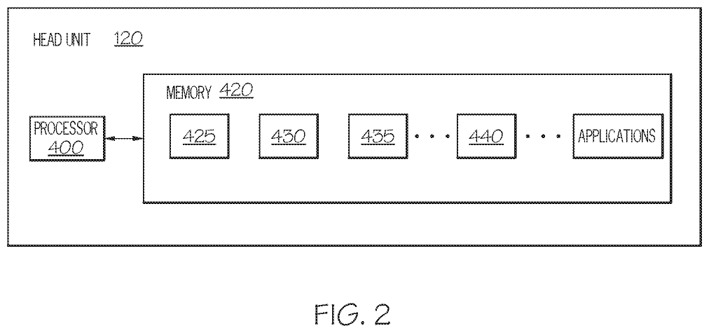

Referring to FIG. 2, the structure and operation of the head unit 120 are explained in detail. The head unit 120 includes a processor 400 and a memory 420 connected to the processor 400. In some embodiments, the memory 420 stores one or more applications 425, 430, 435 and 440, as shown in FIG. 2. The head unit 120 includes other components which are omitted here for convenience of the description of the embodiments. The sensors 150 as shown in FIG. 1 provide various data points to the processor 400 which in turn processes such data points for various purposes. The processor 400 analyzes the data points from the sensors 150 to make various determinations. In some embodiments, the processor 400 analyzes the data to determine whether such data points are stored or discarded, and if stored, will be stored on-board, or externally stored. In other embodiments, the processor 400 analyzes the data to determine a necessary action or reaction to the data points. For example, the processor 400 receives data points from sensors such as an accelerometer, analyzes the data points and finds that the vehicle 100 may be at risk of a crash situation. The processor 400 then may make a determination to cause an action to occur, such as stopping the vehicle 100, or outputting a warning requesting to slow the driving speed of the vehicle 100.

As shown in FIG. 2, the processor 400 may run one or more applications concurrently. At the same time, the processor 400 may process and analyze data points. The computing power of the processor 400 may vary based on processing tasks that are being handled by the processor 400. The computing power of the processor 400 may be able to handle multiple tasks simultaneously. The processor 400 also performs processing of vehicle data, including compression and/or decompression of vehicle data. In addition, the processor 400 performs encryption and/or decryption of vehicle data that are received from external systems via the network 200.

In FIG. 2, one processor 400 is shown, but the vehicle 100 may include one or more processors. One or more processors may be arranged at various locations in the vehicle 100. In some embodiments, the head unit 120 may include two or more processors. In some embodiments, the sensors 150 may be associated with one or more processors for controlling operations of the sensors 150. Other vehicle components such as an air bag may be associated with a controller for controlling an airbag and may operate under the control of the head unit 120.

The memory 420 stores various programs for execution by the processor 400. In some embodiments, the memory 420 stores machine language based programs that process data points. Additionally, or alternatively, the memory 420 stores a deep learning program, a neural network program, a pattern recognition program, etc. that is capable of learning driving patterns of the vehicle 100, learning crash situations of the vehicle 100, etc. In other embodiments, the program stored in the memory 420 further recognizes and modifies user profiles such that vehicle settings can be changed accordingly. The memory 420 further stores various programs relating to analysis of data points of the sensors 150 and/or the sensors 170. The memory 420 also stores various application programs such as media players, a navigation program, programs used in the vehicle settings, etc.

In some embodiments, the memory 420 also stores a compression program 425 that compresses selective data points. The memory 420 further stores a decompression program 430 to decompress data received from the surrounding vehicles 210 and/or external servers. Alternatively, one program may perform compression and decompression. In other embodiments, the memory 420 also stores encryption and/or decryption programs 435 in order to encrypt data points from the sensors 150, 170 prior to transmission and/or decrypt data received from the surrounding vehicles 210 and/or external servers 220, 240, 260, receivers 280, 285, or central server 300.

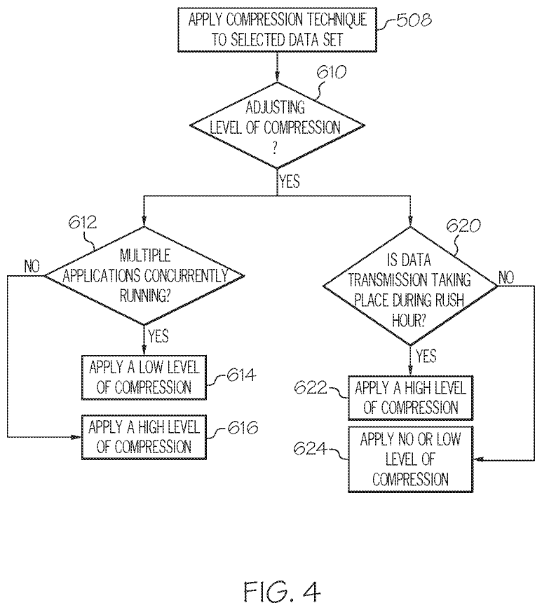

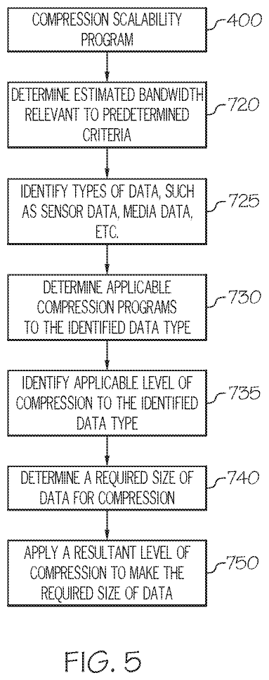

In some embodiments, the memory 420 further stores a compression scalability program 440 that analyzes multiple relevant factors and determines a level of compression to be performed. The compression scalability program 440 checks various factors such as the status of bandwidth capacity, types of data, types of files, etc. and determines a suitable level of compression. The operation of the compression scalability program 440 will be described in detail, in connection with FIGS. 4-5 below.

As shown in FIGS. 1 and 2, the storage 140 may be connected to the head unit 120 for storing more data points. In some embodiments, the storage 140 may have relatively large storage capacity and may be used as long-term storage. In some embodiments, the storage 140 may include a hard drive or a solid state drive.

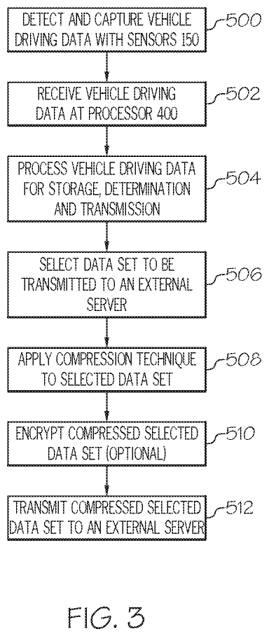

FIG. 3 depicts a flow chart of a method of compressing vehicle driving data according to one or more embodiments shown and described herein. While the vehicle 100 is driving, the sensors 150 generate various data points that are sent to the head unit 120. The head unit 120 captures vehicle driving data from the sensors 150 (Step 500). The processor 400 of the head unit 120 receives the vehicle driving data (Step 502). At Step 504, the processor 400 processes vehicle driving data to perform various processing functions. For example, the vehicle driving data may be processed to determine whether to store or discard such data, and if determined to be stored, to determine a storage location, such as on-board in the storage 140, or externally at a cloud server, such as the edge server 220, 240, or 260, or the central server 300. As another example, the processor 400 may process the vehicle driving data to make various determinations. The processor 400 may analyze the vehicle driving data to learn that the vehicle 100 may be in a near-crash situation. The processor 400 may analyze the vehicle driving data to determine that the vehicle 100 is deviating from normal driving patterns. The processor 400 may analyze and process the vehicle driving data for many other use cases.

At Step 506, the processor 400 may select data sets to be transmitted to an external server, such as the edge servers 220, 240, 260, or the central server 300. In other embodiments, the processor 400 may select data sets to be transmitted to the surrounding vehicles 210 as part of a V2V communication exchange. The processor 400 runs the compression program 425 and the compression scalability program 440 stored in the memory 420 (FIG. 2) to the selected data set (Step 508). Additionally, the processor 400 may run encryption software to encrypt the selected data set along with compression of the selected data set (Step 510). Encryption of the selected data set may be advantageous to provide more data security. For instance, if the selected data set has privacy information, such as a driver's identification, vehicle identification number (VIN), etc., encrypting the selected data set may protect data security of such privacy information.

In some embodiments, the compression program 425 primarily reduces the demands for bandwidth when transferring text, images, and video. Compression reduces the size of the data and therefore, the volume of data required for transmitting digital information such as images, media, documents, etc. may be reduced. Accordingly, using the same bandwidth capacity, more data, once compressed, may be transmitted over the network 200.

Various data compression techniques are available in connection with data transmission and storage. One type of data compression techniques utilizes fewer bits for encoding a message. Another type of data compression techniques includes transmitting frames only when the current frames are different from a previous frame. That way a total amount of data transmitted may be reduced. Another type of data compression techniques is to approximate and transmit a message while not transmitting the message exactly, which is referred to as lossy compression. The compression program used in the embodiments herein may not be limited to a particular compression program and be implemented with various compression programs. The compression program used in the embodiments herein also may implement compression techniques that are in use with data transmission over cellular networks.

In some embodiments, compression may differ based on the type of data to be transmitted. Particular data types may be more readily compressible. For instance, media file formats may be subject to more compression, such as images subject to MPEG compression techniques. In some embodiments, other types of data, such as sensor data, may not be readily compressible.

In some embodiments, the compression program stored in the memory 420 may compress data to have a ZIP file format. The ZIP file format is supported by many compression programs and various operating systems may support the ZIP file format. ZIP files are archives that store multiple files such that files contained in the archives can be compressed using many different methods. Because the files in a ZIP archive are compressed individually, the entire archive may not need to be compressed or decompressed and the tiles may be extracted, or new ones may be added. One compression method used to support a LIP file format is DEFLATE, which is described in Internet Engineering Task Force (“IETF”) Request for Comments (“RFC”) 1951.

Where the compression program supports a ZIP file format, encryption may be implemented in various ways, such as setting up a password with ZIP files. In other embodiments, encryption may use a paring of a public key/private key. To a large extent, data transmission from the vehicle 100 over the network 200 is to broadcast data that can be potentially received by any receiving party. If the pairing of the public key/private key is used, only a limited party, such as the central server 300 in FIG. 1, can decrypt the encrypted data by using the private key. In other words, unintended receiving parties such as other vehicles may be aware of the public key, but the private key may be available only to the central servers 300.

By way of example, the RSA encryption algorithm may be used in the embodiments described herein. The RSA encryption algorithm is a public-key cryptosystem for both encryption and authentication. As another example, the MD5 algorithm is intended for digital signature applications, where a large file needs to be compressed in a secure manner before being encrypted with a private key under a public-key cryptosystem such as RSA, as discussed in Network Working Group RFC 1321 (April 1992).

The processor 400 may run the decryption program 435 to decrypt data received from the external servers such as servers 220, 240, 260 and 300 and/or the surrounding vehicles 210 as shown in FIG. 1. In some embodiments, encryption of data may take place after data is compressed. That way, it is possible to provide effective encryption of data and more data can be encrypted. In other embodiments, encryption of data may take place first and then the encrypted data may be subject to compression.

Subsequent to compressing the selected data set, the compressed data set is sent to the external servers 220, 240, 260 and 300 and/or the surrounding vehicle 210. (Step 512). Through compression, the volume of data for transmission may be fairly reduced. By way of example, about 50% volume reduction of data to be transmitted may be achieved in some embodiments after compression. Compression of data may enable more information to be transmitted via the same bandwidth capacity. When compressed data is transmitted over the network 200, more information can be sent.

Compression of data is performed once a level of compression is determined by running the compression scalability program 440. In some embodiments, the compression scalability program 440 as shown in FIG. 2 determines whether a high level of compression or a low level of compression that is lower than the high level of compression is to be applied based on multiple factors. For example, applying a high level of compression may involve a large reduction of data size and result in a smaller volume of data for transmission. Applying a low level of compression may involve a small reduction of data size from the original data and result in a smaller reduction from the original data volume.

In order to make the determination as to whether a high level of compression or a low level of compression is to be applied, the compression scalability program 440 may consider various parameters affecting the determination of the compression level. In some embodiments, the compression scalability program 440 accesses and/or retrieves parameters such as the bandwidth congestion status or bandwidth availability status. Also, the compression scalability program 440 determines a type of data to be compressed, for example, whether data corresponds to engine data, or media files, in order to determine compressibility of the data types. As discussed above, the media files may be more readily compressible, as opposed to engine data, which may not be readily compressible. Then the compression scalability program 440 may determine, by way of example, that a high level compression may be applied to the media files and a low level compression with a faster algorithm may be applied to the engine data.

The compression scalability program 440 further stores association between data types and an applicable level of compression. Thus, once the compression scalability program 440 identifies the data type, it may make a determination whether a high level compression is to be applied, or a low level compression is to be applied. Once a data type is identified, the compression scalability program 440 is configured to determine applicable compression programs for the identified data type.

The step of compressing the selected date set of FIG. 3 (Step 508) is discussed more in detail with respect to FIG. 4. FIG. 4 depicts a flow chart of compressing vehicle driving data with scalability according to one or more embodiments shown and described herein. In order to apply the compression technique to the selected data set at Step 508 of FIG. 3, the vehicle data compression method determines whether a level of compression is adjusted, rather than applying the compression technique uniformly (Step 610).

There are several situations where the level of compression needs to be adjusted, as shown in FIG. 4. In some embodiments, it is determined whether multiple applications are concurrently running by the processor 400 (Step 612). While the processor 400 is executing multiple high load applications concurrently, it likely uses high computing power. Although compressing data sets may not consume high computing capacity, it may be desirable to avoid adding more computing burden on the processor 400. Then the level of compression may be adjusted to be minimal, or no compression may be applied to the data set. As shown in FIG. 4, a low level of compression may be applied based on the computing power used by the processor 400 (Step 614). If the computing power used by the processor 400 may be small, for example, by running a few applications, or an application requiring low computing power, then a high level of compression may be applied to the selected data set. (Step 616).

In other embodiments, it is determined whether data transmission from the vehicle 100 will take place during rush hour. (Step 620). In some embodiments, the rush hour may indicate a time frame indicative of high network traffic. High network traffic may be associated with higher network usage cost and/or low signal strength. For example, a commuting rush hour may correspond to the rush hour as many vehicles are driving on the road and may involve high network traffic. In other embodiments, a non-commuting rush hour may experience high network traffic, for example, traffic being blocked due to the accident and many vehicles are incapable of moving on the road. If the data transmission may take place during rush hour, then a high level of compression is applied in order to reduce the network traffic. (Step 622). If the network is slow, or experience relatively smooth traffic, then a low level of compression is applied. (Step 624).

In other embodiments, the level of compression may vary based on other factors and considerations. For instance, the level of compression will likely be high when vehicles drive in urban settings. On the other hand, the level of compression may be relatively low or zero when vehicles are driving in a remote area that has low network traffic.

FIG. 5 is a flow chart of the compression scalability program 440 according to one or more embodiments shown and described herein. As shown in FIG. 5, an estimated bandwidth use relevant to predetermined criteria is determined (Step 720). As one example, the predetermined criteria includes whether the time is rush hour or non-rush hour. Thus, a first estimated bandwidth use relevant to rush hour and a second estimated bandwidth use relevant to non-rush hour are predetermined. In some embodiments, historical usage data may be used to determine the first estimated bandwidth and the second estimated bandwidth. The historical usage data reflects the bandwidth capacity provided and available, population of a particular geographical area, a number of vehicles operating in that area during a predetermined time frame of a day at point of interest locations, etc. Parameters indicative of the estimated bandwidth use are pre-stored in the memory 420, in some embodiments, parameters may be stored in the form of numerical values. The estimated bandwidth use may be adjusted to reflect any ongoing change and actual use patterns on a regular basis.

In some embodiments, the compression scalability program 440 has a relevant set of threshold information with respect to the bandwidth capacity. For instance, a maximum bandwidth capacity of relevant communication channels and specific bandwidth limits relevant to the determination of the level of compression are predetermined and pre-stored. By way of example, each bandwidth capacity estimated for rush hour and non-rush hour is predetermined and pre-stored as discussed above in connection with Step 720. Accordingly, the compression scalability program 440 can retrieve and/or access the relevant threshold information as to the bandwidth in advance.

The compression scalability program 440 is then configured to identify types of data, such as sensor data, media data, etc. (Step 725). The compression scalability program 440 determines the compressible nature of data based on the data type. (Step 730). Thus, sensor data are, for example, more likely to be less compressible, and media files may be more compressible. Based on the determination, an applicable level of compression may be identified with respect to the data. (Step 735). With this set of relevant information available, the compression scalability program 440 determines a required size of data for compression that is indicative of a level of compression. (Step 740). Based on the required size of data for compression, the bandwidth relevant to the criteria and the data type, a resulting level of compression is applied to make the required size of data. (Step 750). The compression scalability program 440 may consider other relevant factors and the relevant factors may not be limited to the ones described in FIG. 5. The compression scalability program 440 is adapted to reflect and make ongoing modifications as parameters relevant to the vehicle 100 and other network environment and settings change.

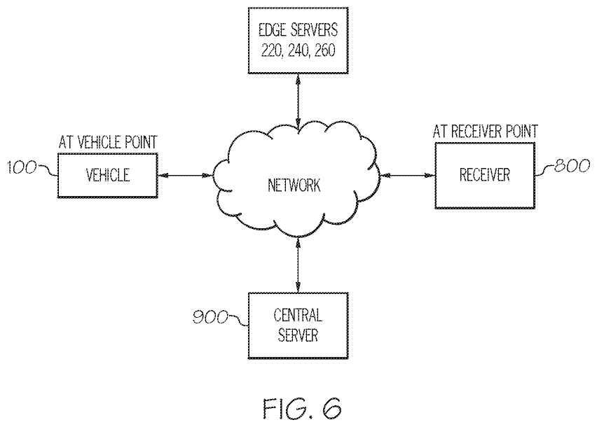

FIG. 6 schematically depicts different compression points of the vehicle data compression system of FIG. 1. As shown in FIG. 6, compression of the vehicle driving data may be performed at a vehicle point, i.e., at the vehicle 100. Additionally, or alternatively, compression of the vehicle driving data may be performed at a remote server such as a receiver 800 in communication with the central server 900. In some embodiments, the receiver 800 may perform compression of data. As shown in FIG. 6, compression of data at the receiver 800 may be adjusted based on many relevant factors.

In some embodiments, the receiver 800 may receive data streams from various vehicles driving in a predetermined geographical area, and/or during a particular time frame. In other embodiments, the receiver 800 may receive data streams including many different types of data, files, videos, applications, etc. In these situations, the level of compression at the receiver 800 may be adjusted to address a particular situation.

In some embodiment, when the receiver 800 receives data streams during rush hour involving high network traffic, the level of compression may increase in order to relieve the network traffic. However, if the network traffic is not busy, or the receiver 800 has relatively high computing availability, the level of compression may be lowered in order to reduce computing load on the receiver 800.

In the embodiments described above, a scalable vehicle data compression method includes steps of detecting and capturing vehicle data with a group of sensors, processing and analyzing a data stream including the vehicle data with a processor, identifying a data type of the data stream, determining an estimated usage of a network bandwidth, determining a current processing load of the processor, determining a level of compression based on the data type, the current processing load of the processor, the estimated usage of the network bandwidth, or a combination thereof, and compressing the data stream with the processor based on the determined level of compression; and transmitting a compressed data stream over a network.

In another embodiment, the step of determining the current processing load further includes determining whether the current processing load of the processor exceeds a predetermined threshold. The step of determining the level of compression further includes upon determination that the current processing load exceeds the predetermined threshold, applying no compression to the data stream. The step of compressing the data stream further includes compressing the data stream to have a predetermined size of data, wherein the predetermined size of data corresponds to the determined level of compression.

In yet another embodiment, the step of determining the level of compression further includes applying a first level of compression to a first type of the data streams and applying a second level of compression to a second type of the data streams. The second type of the data streams is more compressible than the first type of the data streams. The first type of the data streams includes the vehicle data from the group of sensors and the second type of the data streams comprises media files.

In yet another embodiment, compressing the data stream further includes applying a first level of compression to the data stream to have a first data size upon the determined level of compression corresponds to a high level, and applying a second level of compression to the data stream to have a second data size upon the determined level of compression corresponds to a low level. The first size of data is smaller than the second size of data.

In yet another embodiment, the scalable vehicle data compression method further includes encrypting the compressed data stream with the processor, and decrypting, with the processor, a second data stream received from an external system. In yet another embodiment, the scalable vehicle data compression method further includes decompressing, with the processor, a second data set received from an external system.

In yet embodiment, the step of detecting and capturing vehicle data with the group of sensors further includes detecting and capturing a first set of vehicle data with a first group of sensors arranged on-board of a first vehicle, and detecting and capturing a second set of vehicle data with a second group of sensors arranged on a second vehicle adjacent to the first vehicle.

In yet another embodiment, the step of detecting and capturing vehicle data further includes detecting and capturing a third set of vehicle data with a third group of sensors arranged on a surrounding of the first vehicle.

In the embodiments described above, a scalable vehicle data compression method, includes receiving, at a receiver comprising a processor and a memory, a plurality of data streams from a group of mobile data sources, storing in the memory estimated usage data of a network data traffic associated with a data transmission time and a data transmission location, identifying one or more data types of the plurality of data streams, retrieving, at the receiver, the estimated usage data, determining a current processing load of the processor of the receiver, determining a level of compression based on the data type, the current processing load of the processor, the estimated usage of the network data traffic, or a combination thereof, compressing the data stream with the processor based on the determined level of compression, and transmitting a compressed data stream over a network to a cloud server.

In yet another embodiment, the scalable vehicle data compression method further includes encrypting the data streams prior to transmitting to the cloud server and decrypting, at the receiver, one or more of the received vehicle data streams that have been encrypted.

In the embodiments described above, a scalable vehicle data compression system, includes a first group of sensors arranged on-board of a first vehicle and operable to detect and capture first vehicle data, a second group of sensors arranged external and adjacent to the first vehicle and operable to detect and capture second vehicle data, one or more processors, one or more memory modules communicatively coupled to the one or more processors, and machine readable instructions stored in the one or more memory modules and upon execution by the one or more processors, performing at least the following: analyzing a data stream including the first vehicle data, the second vehicle data, or both; identifying a type of the data stream; determining an estimated usage of a network bandwidth; determining a current processing load of the processor; determining a level of compression based on the data type, the current processing load of the processor, the estimated usage of the network bandwidth, or a combination thereof, and compressing the data stream with the processor based on the determined level of compression, and a communication unit that transmits a compressed data stream over a network.

In yet another embodiment, the scalable vehicle data compression system further includes machine readable instructions performing determining whether the current processing load of the processor exceeds a predetermined threshold; and upon determination that the current processing load exceeds the predetermined threshold, applying no compression to the data stream.

In yet another embodiment, the scalable vehicle data compression system further includes machine readable instructions performing determining compressing the data stream to have a predetermined size of data, where the predetermined size of data correspond to the determined level of compression.

In yet another embodiment, the scalable vehicle data compression system further includes machine readable instructions further performing applying a first level of compression to a first type of the data streams and applying a second level of compression to a second type of the data streams, wherein the second type of the data streams is more compressible than the first type of the data streams.

In yet another embodiment, the first type of the data streams comprises the vehicle data from the group of sensors and the second type of the data streams comprises media files. In some embodiments, the scalable vehicle data compression system further includes machine readable instructions further performing applying a first level of compression to the data stream to have a first data size upon the determined level of compression corresponds to a high level; and applying a second level of compression to the data stream to have a second data size upon the determined level of compression corresponds to a low level, where the first size of data is smaller than the second size of data.

In yet another embodiment further performing encrypting the compressed data stream with the processor; and decrypting, with the processor, a second data stream received from an external system.

In yet another embodiment, the scalable vehicle data compression system further includes machine readable instructions further performing detecting and capturing a first set of vehicle data with a first group of sensors arranged on-board of a first vehicle; detecting and capturing a second set of vehicle data with a second group of sensors arranged on a second vehicle adjacent to the first vehicle; and detecting and capturing a third set of vehicle data with a third group of sensors arranged on a surrounding of the first vehicle.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A scalable vehicle data compression method, comprising:
detecting and capturing vehicle data with a group of sensors;
processing and analyzing one or more data streams including the vehicle data with a processor;
determining (i) a data type of the data stream, (ii) an estimated usage of a network bandwidth, (iii) a current processing load of the processor, or a combination thereof;
determining a level of compression based on the data type, the estimated usage of the network bandwidth, the current processing load of the processor, or a combination thereof; and
compressing the one or more data streams with the processor based on the determined level of compression; and
transmitting a compressed data stream over a network.

2. The compression method of claim 1, wherein the step of determining the current processing load further comprises determining whether the current processing load of the processor exceeds a predetermined threshold; and
the step of determining the level of compression further comprises: upon determination that the current processing load exceeds the predetermined threshold, applying no compression to the data stream.

3. The compression method of claim 1, wherein the step of compressing the data stream further comprises:
compressing the one or more data streams to have a predetermined size of data, wherein the predetermined size of data correspond to the determined level of compression.

4. The compression method of claim 1, wherein the step of determining the level of compression further comprises:
applying a first level of compression to a first type of the one or more data streams; and
applying a second level of compression to a second type of the one or more data streams;
wherein the second type of the data streams is more compressible than the first type of the data streams.

5. The compression method of claim 4, wherein the first type of the data streams comprises the vehicle data from the group of sensors and the second type of the data streams comprises media files.

6. The compression method of claim 1, wherein the step of compressing the one or more data streams further comprises:
applying a first level of compression to the one or more data streams to have a first data size when the determined level of compression corresponds to a high level; and
applying a second level of compression to the one or more data streams to have a second data size when the determined level of compression corresponds to a low level;
wherein the first data size is smaller than the second data size.

7. The compression method of claim 1, further comprising:
encrypting the compressed data stream with the processor; and
decrypting, with the processor, another data stream received from an external system.

8. The compression method of claim 1, further comprising:
decompressing, with the processor, another data stream received from an external system.

9. The compression method of claim 1, wherein the step of detecting and capturing vehicle data with the group of sensors further comprises:
detecting and capturing a first set of vehicle data with a first group of sensors arranged on-board of a first vehicle; and
detecting and capturing a second set of vehicle data with a second group of sensors arranged on a second vehicle adjacent to the first vehicle.

10. The compression method of claim 9, wherein the step of detecting and capturing vehicle data further comprises:
detecting and capturing a third set of vehicle data with a third group of sensors arranged on a surrounding of the first vehicle.

11. A scalable vehicle data compression system, comprising:
a group of sensors arranged on-board of a vehicle and operable to detect and capture vehicle data;
one or more processors coupled to the group of sensors and operable to receive one or more data streams including the vehicle data;
one or more memory modules communicatively coupled to the one or more processors; and
machine readable instructions stored in the one or more memory modules and upon execution by the one or more processors, performing at least the following:
analyzing the one or more data streams including the vehicle data;
determining (i) a data type of the data stream, (ii) an estimated usage of a network bandwidth, (iii) a current processing load of the processor, or a combination thereof;
determining a level of compression based on the data type, the estimated usage of the network bandwidth, the current processing load of the processor, or a combination thereof; and
compressing the one or more data streams with the processor based on the determined level of compression; and
a communication unit that transmits a compressed data stream over a network.

12. The scalable vehicle data compression system of claim 11, wherein the machine readable instruction of determining the current processing load further performs determining whether the current processing load of the processor exceeds a predetermined threshold; and
the machine readable instruction of determining the level of compression further performs upon determination that the current processing load exceeds the predetermined threshold, applying no compression to the data stream.

13. The scalable vehicle data compression system of claim 11, wherein the machine readable instruction of compressing the one or more data streams further perform compressing the one or more data streams to have a predetermined size of data, wherein the predetermined size of data correspond to the determined level of compression.

14. The scalable vehicle data compression system of claim 11, wherein the machine readable instruction of determining the level of compression further perform:
applying a first level of compression to a first type of the one or more data streams; and
applying a second level of compression to a second type of the one or more data streams;
wherein the second type of the data streams is more compressible than the first type of the data streams.

15. The scalable vehicle data compression system of claim 14, wherein the first type of the data streams comprises the vehicle data from the group of sensors and the second type of the data streams comprises media files.

16. The scalable vehicle data compression system of claim 15, wherein the machine readable instruction of compressing the data stream further perform:
applying a first level of compression to the data streams to have a first data size when the determined level of compression corresponds to a high level; and
applying a second level of compression to the data streams to have a second data size when the determined level of compression corresponds to a low level;
wherein the first data size is smaller than the second data size.

17. The scalable vehicle data compression system of claim 11, wherein the machine readable instructions further perform the following:
encrypting the compressed data stream with the processor; and
decrypting, with the processor, another data stream received from an external system.

18. The scalable vehicle data compression system of claim 11, wherein the machine readable instructions further performing the following:
detecting and capturing a first set of vehicle data with a first group of sensors arranged on-board of a first vehicle;
detecting and capturing a second set of vehicle data with a second group of sensors arranged on a second vehicle adjacent to the first vehicle; and
detecting and capturing a third set of vehicle data with a third group of sensors arranged on a surrounding of the first vehicle.

19. A scalable vehicle data compression system, comprising:
a processor;
a data communication unit operable to receive a plurality of data streams from a group of mobile data sources;
one or more memory coupled to the processor and configured to store estimated usage data of a network data traffic associated with a data transmission time and a data transmission location, wherein the one or more memory further store machine readable instructions stored in the one or more memory and upon execution by the one or more processors, performing at least the following:
determining (i) a data type of the data stream, (ii) an estimated usage of a network bandwidth, (iii) a current processing load of the processor, or a combination thereof;
retrieving the estimated usage data;
determining a level of compression based on the one or more data types, the estimated usage of the network data traffic, the current processing load of the processor, or a combination thereof; and
compressing the plurality of data streams with the processor based on the determined level of compression; and
wherein the data communication unit is further operable to transmit one or more compressed data streams over a network to a cloud server.

20. The compression system of claim 19, wherein the machine readable instructions stored in the one or more memory, upon execution by the one or more processors, further perform at least the following:
encrypting the one or more data streams prior to transmitting to the cloud server;
decrypting, with the processor, one or more received vehicle data streams that have been encrypted; and
decompressing the one or more received data streams that have been compressed.
